(19) United States
(12) Patent Application Publication
(10) Pub. No.: US 2015/0049571 A1
(43) Pub. Date: Feb. 19, 2015

(54) MEMORY CONTROL DEVICE, CONTROL METHOD OF MEMORY CONTROL DEVICE, INFORMATION PROCESSING APPARATUS

(71) Applicant: FUJITSU LIMITED, Kawasaki-shi (JP)

(72) Inventor: Takeo Nakamura, Kawasaki (JP)

(21) Appl. No.: 14/326,759

(22) Filed: Jul. 9, 2014

(30) Foreign Application Priority Data
Aug. 16, 2013 (JP) 2013-169256

(51) Int. Cl. G11C 8/18

(52) U.S. Cl. CPC G11C 8/18
USPC 365/233.1

(57) ABSTRACT

A set value retaining register stores therein, in an associated manner, control information on a memory and a clock frequency that is supplied to the memory. A memory access control circuit determines whether control information associated with the specified clock frequency is present in the set value retaining register. When the memory access control circuit determines that the control information associated with the specified clock frequency is not present in the set value retaining register, a memory tuning circuit decides control information that is associated with the specified clock frequency. When the memory access control circuit determines that the control information associated with the specified clock frequency is not present in the set value retaining register, a data transmission/reception module controls the memory on the basis of the control information decided by the memory tuning circuit.

### CROSS-REFERENCE TO RELATED APPLICATION

This application is based upon and claims the benefit of priority of the prior Japanese Patent Application No. 2013-169256, filed on Aug. 16, 2013, the entire contents of which are incorporated herein by reference.

### FIELD

The embodiments discussed herein are directed to a memory control device, a control method of a memory control device, and an information processing apparatus.

### BACKGROUND

In recent years, there have been increasing demands for electrical power saving with respect to, in addition to mobile devices, servers or personal computers (PCs). Consequently, dynamic voltage and frequency scaling (DVFS) that dynamically changes voltages and frequencies of electronic components, such as central processing units (CPUs), is becoming widely used.

A conventional technology that controls, in accordance with a high-speed operation request and a low-speed operation request, voltages of power supplies with respect to memory channels in computers, such as servers or PCs, that includes main memories.

For example, unlike CPUs, in memory interfaces that use Dual Inline Memory Modules (DIMMs) or the like, optimum setting varies for each combination of a frequency and a voltage and is decided by performing tuning. Consequently, when an attempt to obtain optimum performance is made for each combination of a frequency and a voltage, the tuning is performed every time the frequency and the voltage vary.

Regarding this technology, for example, there is a conventional technology that tests relationship between an operation speed of a memory and a voltage of the power supply of the memory and decides a voltage to be supplied to a memory.

Patent Document 1: Japanese National Publication of International Patent Application No. 2012-523052

Patent Document 2: Japanese Laid-open Patent Publication No. 04-167046

However, it takes a certain time to perform the tuning of a memory interface. Furthermore, because a memory bus is not able to be used during the tuning, during this time, a system is not able to eventually use a memory module.

With the conventional technology that controls voltages of power supplies in accordance with a high-speed operation request and a low-speed operation request, memory tuning is performed every time an instruction to change a setting of a frequency or a voltage is received. It is conceivable that it takes a long time to perform the tuning depending on the performance of a memory and thus the time for which a memory bus is not able to be used becomes long. Specifically, there may possibly be a case in which it takes a long time to finish a setting change in a frequency or a voltage. This also occurs in the conventional technology that performs a test to decide a voltage supplied to a memory.

### SUMMARY

According to an aspect of an embodiment, a memory control device includes: a storing unit that stores therein, in an associated manner, control information on a memory and a clock frequency that is supplied to the memory; a determining unit that receives a specification of a clock frequency supplied to the memory and that determines whether control information that is associated with the specified clock frequency is present in the storing unit; a deciding unit that decides, when the determining unit determines that the control information associated with the specified clock frequency is not present in the storing unit, the control information that is associated with the specified clock frequency; and a control unit that controls, on the basis of the control information decided by the deciding unit, the memory when the determining unit determines that the control information associated with the specified clock frequency is not present in the storing unit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram illustrating an information processing apparatus according to a first embodiment;

FIG. 2 is a schematic diagram illustrating information stored in a set value retaining register according to the first embodiment;

FIG. 3 is a flowchart illustrating the flow of a memory control process performed by a memory control device according to the first embodiment;

FIG. 4 is a flowchart illustrating the flow of a memory control process performed by a memory control device according to a second embodiment when a system is booted up;

FIG. 5 is a block diagram illustrating an information processing apparatus according to a third embodiment;

FIG. 6 is a schematic diagram illustrating information stored in a set value retaining register according to the third embodiment; and

FIG. 7 is a flowchart illustrating the flow of a memory control process performed by a memory control device according to the third embodiment.

### DESCRIPTION OF EMBODIMENTS

Preferred embodiments of the present invention will be explained with reference to accompanying drawings. The memory control device, the control method of the memory control device, and the information processing apparatus disclosed in the present invention are not limited to the embodiments described below.

### [a] First Embodiment

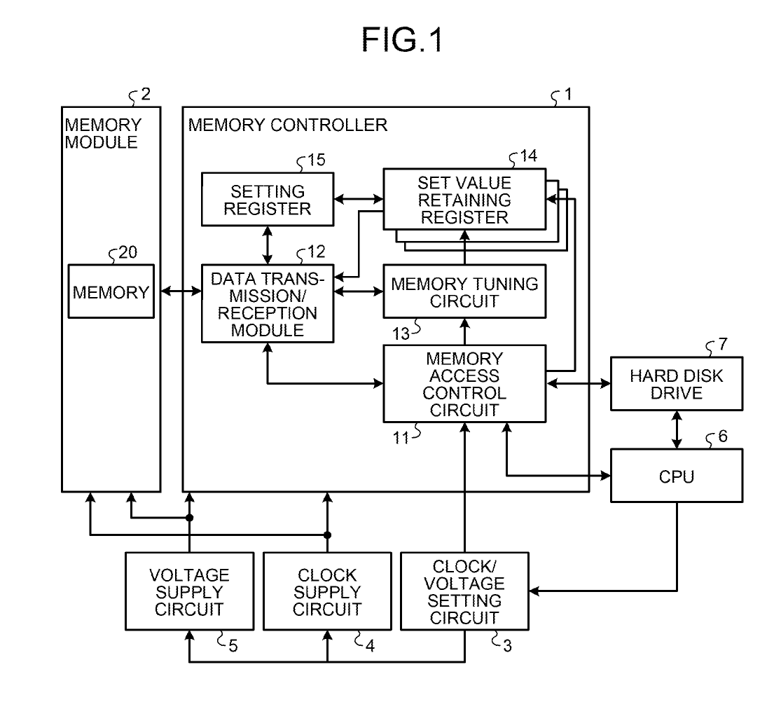

FIG. 1 is a block diagram illustrating an information processing apparatus according to a first embodiment. The information processing apparatus according to the first embodiment includes a memory controller 1 that is a memory control device, a memory module 2, a clock/voltage setting circuit 3, a clock supply circuit 4, a voltage supply circuit 5, a central processing unit (CPU) 6 that is an arithmetic processing unit, and a hard disk drive 7.

The CPU 6 is connected to the memory controller 1 and to the hard disk drive 7 by a bus. The CPU 6 sends and receives data to and from a memory 20, such as a dynamic random access memory (DRAM), that is mounted on the memory module 2 via the memory controller 1. Specifically, the CPU 6 sends a command for reading/writing of data to a memory access control circuit 11, which will be described later, and sends and receives data to and from the memory access control circuit 11.

Furthermore, the CPU 6 determines whether the state of its own device satisfies a change condition of the setting of a frequency and a voltage. If the change condition is satisfied, the CPU 6 notifies the clock/voltage setting circuit 3 of a setting change in the frequency and the voltage. In the embodiment, a description will be given of a case in which a setting change in a frequency and a voltage is sent to the clock/voltage setting circuit 3 as a notification; however, a setting change in a frequency and a voltage may also be notified as a process performed by software that is executed by the CPU 6. Furthermore, in the first embodiment, in addition to the notification of the setting change, the CPU 6 sends a notification of a value of each of the frequency and the voltage, i.e., a change value.

In the first embodiment, a description will be given of a case in which, as the setting of a frequency and a voltage, there are three types of settings, i.e., “normal setting”, “high performance setting”, and “low electrical power consumption setting”. The normal setting mentioned here is the setting in which the processing speed and the electrical power consumption of the memory 20 are balanced. The normal setting is used when a frequency and a voltage are not particularly set after the information processing apparatus is booted up. Furthermore, in the normal setting, the frequency is, for example, 1600 MHz and the voltage is, for example, 1.35 V. This normal setting mentioned here corresponds to an example of “a first setting”. The high performance setting mentioned here is the setting in which a priority is given to the processing speed of the memory 20. In the high performance setting, the frequency is, for example, 1800 MHz and the voltage is, for example, 1.50 V. The high performance setting mentioned here corresponds to an example of “a second setting”. The low electrical power consumption setting mentioned here is the setting in which a priority is given to a reduction of electrical power consumed by the memory 20. In the low electrical power consumption setting, the frequency is, for example, 800 MHz and the voltage is, for example, 1.20 V. The low electrical power consumption setting mentioned here corresponds to “a third setting”.

Specifically, in the first embodiment, when the information processing apparatus is booted up, the memory controller 1, the clock supply circuit 4, and the voltage supply circuit 5 operate in the normal setting. Furthermore, for example, if requests that are to be sent to the memory module 2 and the number of which is equal to or greater than a threshold or more are accumulated in a pipeline of a cache, the CPU 6 notifies the clock/voltage setting circuit 3 of a setting change indicating that the setting is to be changed to the high performance setting. Furthermore, if requests that are to be sent to the memory module 2 and the number of which is less than the threshold, the CPU 6 notifies the clock/voltage setting circuit 3 of a setting change indicating that the setting is to be changed to the low electrical power consumption setting.

At this point, for example, if software that is executed by the CPU 6 sends a notification of a setting change, the software sends the notification of the setting change as follows. Namely, the software monitors the load status, the electrical power consumption of the information processing apparatus, or the like. If the load is high, the software notifies the clock/voltage setting circuit 3 of the setting change indicating that the setting to be is changed to the high performance setting. Furthermore, if the load is low, the software notifies the clock/voltage setting circuit 3 of a setting change indicating that the setting is to be changed to the low electrical power consumption.

Furthermore, the CPU 6 also reads and writes data from and to the hard disk drive 7.

The hard disk drive 7 sends and receives data to and from the CPU 6. Furthermore, in response to an instruction from the CPU 6, the hard disk drive 7 sends and receives data to and from the memory 20, such as a DRAM, that is mounted on the memory module 2 via the memory controller 1.

The clock/voltage setting circuit 3 stores therein, as an initial setting, a value of each of a frequency and a voltage that are used in the normal setting. Then, when the information processing apparatus is booted up, the clock/voltage setting circuit 3 notifies the memory access control circuit 11 of the frequency and the voltage used in the normal setting.

Furthermore, the clock/voltage setting circuit 3 notifies the clock supply circuit 4 of a value of the frequency used in the normal setting. Furthermore, the clock/voltage setting circuit 3 notifies the voltage supply circuit 5 of a value of the voltage used in the normal setting.

Furthermore, the clock/voltage setting circuit 3 receives, from the CPU 6, a notification of the setting change in the frequency and the voltage. Then, the clock/voltage setting circuit 3 notifies the memory access control circuit 11 of the value of each of the frequency and the voltage specified by the CPU 6. Furthermore, the clock/voltage setting circuit 3 notifies the clock supply circuit 4 of the value of the frequency specified by the CPU 6. Furthermore, the clock/voltage setting circuit 3 notifies the voltage supply circuit 5 of the value of the voltage specified by the CPU 6.

At this point, in the first embodiment, the clock/voltage setting circuit 3 receives an input of the value of each of the frequency and the voltage from the CPU 6; however, another method may also be used. For example, the clock/voltage setting circuit 3 may store therein, in an associated manner, the setting types of the frequency and the voltage and the values of the frequency and the voltage, may receive information on a setting type of a frequency and a voltage from the CPU 6, and may acquire the value of each of the frequency and the voltage that are associated with the received setting type.

The clock supply circuit 4 receives, from the clock/voltage setting circuit 3, a notification of a clock frequency supplied to each of the memory controller 1 and the memory module 2. Then, the clock supply circuit 4 supplies the received clock frequency to the memory controller 1 and the memory module 2.

The voltage supply circuit 5 receives, from the clock/voltage setting circuit 3, a value of the voltage of the electrical power supplied to each of the memory controller 1 and the memory module 2. Then, the clock supply circuit 4 supplies the electrical power having the voltage with the notified value to the memory controller 1 and the memory module 2.

The memory module 2 is a module on which the memory 20, such as a DRAM, is mounted. For example, the memory module 2 is a 4 RANK-DIMM.

The memory module 2 receives a supply of electrical power from the voltage supply circuit 5. Furthermore, the memory module 2 receives a supply of a clock from the clock supply circuit 4. Then, by using the electrical power supplied from the voltage supply circuit 5, the memory module 2 operates in the frequency of the clock supplied from the clock supply circuit 4.

For example, in response to the control performed by a data transmission/reception module 12 in the memory controller 1, the memory module 2 sends and receives data.

The memory controller 1 includes the memory access control circuit 11, the data transmission/reception module 12, a memory tuning circuit 13, a set value retaining register 14, and a setting register 15.

The memory controller 1 receives a supply of a clock from the clock supply circuit 4 and receives a supply of electrical power from the voltage supply circuit 5. Then, each of the units in the memory controller 1 operates by using the electrical power supplied from the voltage supply circuit 5 with the frequency of the clock supplied from the clock supply circuit 4.

The memory access control circuit 11 receives a value of each of the frequency and the voltage from the block/voltage setting circuit 3. The memory access control circuit 11 searches the set value retaining register 14 for the value of each of the received frequency and the voltage and the control information that is associated with the received frequency and the voltage. The control information mentioned here includes phase adjustment information that is used to adjust the phase of a data strobe signal (DQS signal) sent from the memory module 2 and a clock and includes cycle adjustment information that is used to adjust the cycle. Furthermore, the control information also includes, for example, delay time information that indicates a delay time of the memory 20 mounted on the memory module 2. In a description below, each of the values included in the control information may also sometimes be referred to as a “set value”.

If the set value retaining register 14 stores therein the value of the received frequency, the value of the received voltage, and the control information that is associated with these values, the memory access control circuit 11 sends, to the data transmission/reception module 12, an instruction indicating that the associated control information is used to control the memory module 2.

In contrast, if the set value retaining register 14 does not stores therein the value of the received frequency, the value of the received voltage, and the control information that is associated with these values, the memory access control circuit 11 instructs the memory tuning circuit 13 to perform the memory tuning in which the received frequency and the voltage are used.

In the first embodiment, when the information processing system is booted up, information is not stored in the set value retaining register 14. Accordingly, when the information processing system is booted up, the memory access control circuit 11 instructs the memory tuning circuit 13 to perform the memory tuning by using the frequency and the voltage that is set in the normal setting. Then, when receiving an instruction to change the setting of the frequency and the electrical power from the CPU 6, the memory access control circuit 11 instructs the memory tuning circuit 13 to perform the memory tuning that is used in the instructed setting. However, the control information that is associated with the setting of the frequency and the electrical power used once for the memory tuning is stored in the set value retaining register 14, which will be described later. Consequently, if an instruction to change the setting of the frequency and the electrical power used once for the memory tuning is received again, the memory access control circuit 11 sends, to the data transmission/reception module 12, an instruction indicating that the control information associated with that setting is used to control the memory module 2. The memory access control circuit 11 corresponds to an example of a “determining unit”.

Furthermore, the memory access control circuit 11 receives, from the CPU 6 or the hard disk drive 7, the writing or reading of data to or from the memory 20. Then, the memory access control circuit 11 sends, to the data transmission/reception module 12, an instruction to write or read the received data. Then, the memory access control circuit 11 receives a response from the data transmission/reception module 12 and sends a response to the CPU 6 or the hard disk drive 7 in accordance with the received response.

If the control information associated with the specified frequency and the electrical power is stored in the set value retaining register 14, the data transmission/reception module 12 receives, from the memory access control circuit 11, a value of each of the frequency and the voltage that are associated with the control information and that are used to control the memory module 2. Then, the data transmission/reception module 12 receives, from the set value retaining register 14, each of the set values that are included in the control information and that are associated with each of the received frequency and the voltage. Then, the data transmission/reception module 12 stores the received set value in the setting register 15. Thereafter, the data transmission/reception module 12 starts using the memory bus by using each of the set values stored in the setting register 15 and then sends and receives data to and from the memory module 2.

Furthermore, if control information associated with the specified frequency and the electrical power is not stored in the set value retaining register 14, the data transmission/reception module 12 receives, from the memory tuning circuit 13, each of the set value that is included in the control information and that is associated with the setting of the frequency and the electrical power. Then, the data transmission/reception module 12 stores the received set values in the setting register 15. Thereafter, the data transmission/reception module 12 starts to use a memory bus by using each of the set values stored in the setting register 15 and then sends and receives data to and from the memory module 2. The data transmission/reception module 12 mentioned here corresponds to an example of a “control unit”.

If the control information that is associated with the specified frequency and the electrical power is not stored in the set value retaining register 14, the memory tuning circuit 13 receives, from the memory access control circuit 11, an instruction to perform the memory tuning for that frequency and that electrical power. Then, the memory tuning circuit 13 performs the memory tuning in the state in which the memory tuning circuit 13 uses the voltage supplied from the voltage supply circuit 5 and the clock supplied from the clock supply circuit 4.

For example, the memory tuning circuit 13 performs a process for adjusting the phase of a clock signal and the phase of a DQS signal and then obtains phase adjustment information. This process is referred to as, for example, “write levelling”. Furthermore, the memory tuning circuit 13 performs a process for adjusting the cycles of the clock signal and the DQS signal and then obtains cycle adjustment information. This process is referred to as, for example, “cycle check”. Furthermore, the memory tuning circuit 13 performs a process for estimating a delay time of the memory 20 and then obtains delay time information. This process is referred to as, for example, “read levelling”.

Then, the memory tuning circuit 13 sends, to the data transmission/reception module 12, the set values, such as the obtained phase adjustment information, the cycle adjustment information, and the delay time information. The memory tuning circuit 13 mentioned here corresponds to an example of a “deciding unit”.

Furthermore, the memory tuning circuit 13 associates the set values, such as the obtained phase adjustment information, the cycle adjustment information, and the delay time information, with the value of each of the frequency and the electrical power used at that time and then stores the values in the set value retaining register 14.

The set value retaining register 14 receives, from the memory tuning circuit 13, the set values, such as the phase adjustment information, the cycle adjustment information, and the delay time information, that is associated with the value of each of the frequency and the electrical power. Then, the set value retaining register 14 associates a set value, such as the phase adjustment information, the cycle adjustment information, or the delay time information, with a value of the frequency and a value of the electrical power and stores the values. The set value retaining register 14 mentioned here corresponds to an example of a “storing unit”.

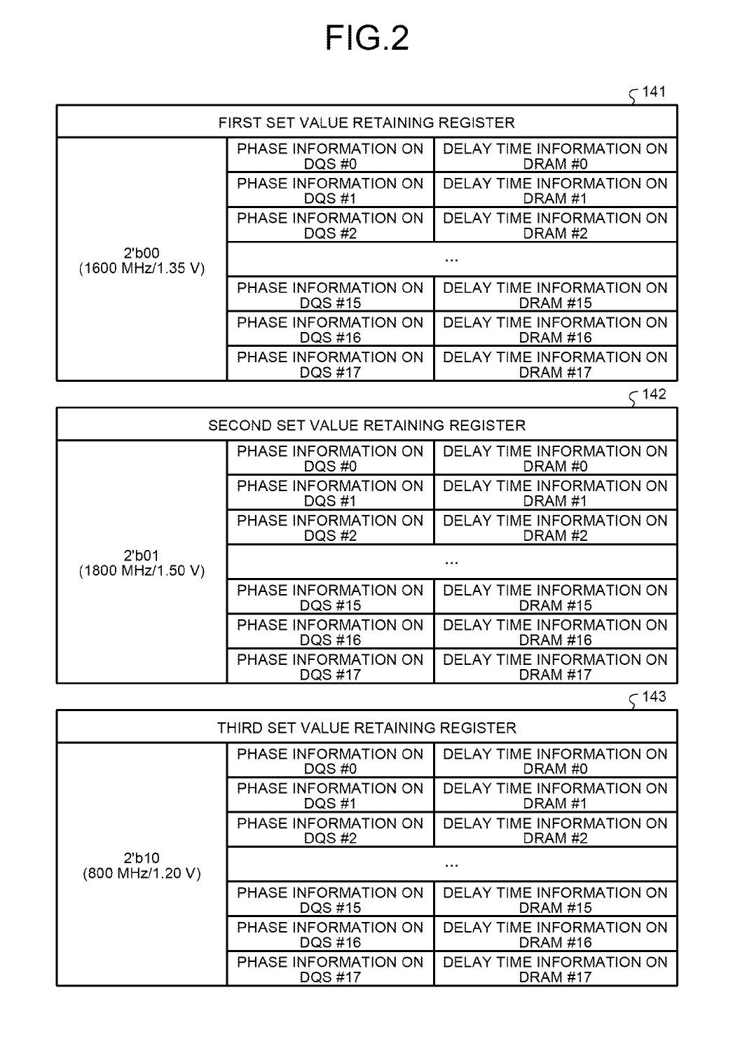

FIG. 2 is a schematic diagram illustrating information stored in a set value retaining register according to the first embodiment. FIG. 2 illustrates, by using a table, the association relationship between the control information and the values of the frequency and the electrical power stored in the set value retaining register 14; however, the format of the information is not particularly limited as long as the association relationship is maintained.

In the first embodiment, the set value retaining register 14 includes a first set value retaining register 141, a second set value retaining register 142, and a third set value retaining register 143.

The first set value retaining register 141 stores therein control information that is associated with the normal setting in which the frequency of 1600 MHz and the voltage of 1.35 V is used. In the first embodiment, the value of the signal that indicates the normal setting is, for example, “2′b00”. In the first embodiment, when the memory tuning circuit 13 receives the frequency and the voltage used for the normal setting from the clock/voltage setting circuit 3, the memory tuning circuit 13 checks whether the first set value retaining register 141 that stores therein the control information associated with “2′b00” is present. Furthermore, when the data transmission/reception module 12 changes the frequency and the voltage to those used for the normal setting, the data transmission/reception module 12 receives the signal with the value of “2′b00” from the memory tuning circuit 13 and searches for the control information that is associated with that value.

Then, as illustrated in FIG. 2, for multiple memory buses each of which connects the memory module 2 and the data transmission/reception module 12, the first set value retaining register 141 stores therein control information that is associated with each of the memory buses. In the first embodiment, the memory module 2 has mounted thereon 18 DRAMs. Furthermore, FIG. 2 illustrates control information obtained when tuning is performed for each of the DRAMs (DRAM #0 to #17) and is performed for each of the DQS signals (DQS #0 to #17) that are output to a memory bus connected to the corresponding DRAM. The phase information illustrated in FIG. 2 includes therein the phase adjustment information, the cycle adjustment information, and the like. Specifically, the data transmission/reception module 12 controls each of the memory buses by using the control information that is associated with each of the memory buses. The reason for this is because an optimum set value varies depending on, for example, the length of the memory bus.

The second set value retaining register 142 stores therein the control information that is associated with the high performance setting in which the frequency of 1800 MHz and the voltage of 1.50 V is used. In the first embodiment, the value of the signal that indicates the high performance setting is, for example, “2′b01”. For multiple memory buses each of which connects the memory module 2 and the data transmission/reception module 12, the second set value retaining register 142 also stores therein control information that is associated with each of the memory buses.

The third set value retaining register 143 stores therein the control information that is associated with the low electrical power consumption setting in which the frequency of 800 MHz and the voltage of 1.20 V is used. In the first embodiment, the value of the signal that indicates the low electrical power consumption setting is, for example, “2′b10”. For multiple memory buses each of which connects the memory module 2 and the data transmission/reception module 12, the third set value retaining register 143 also stores therein control information that is associated with each of the memory buses.

The setting register 15 receives, from the data transmission/reception module 12, an input of a set value that is used to control the memory module 2. Then, the setting register 15 stores therein the received set value. Thereafter, the information retained in the setting register 15 is used by the data transmission/reception module 12 when the data transmission/reception module 12 controls the memory module 2.

Furthermore, when the settings of the frequency and the voltage are changed, the setting register 15 is reset, receives a set value that is associated with the new setting of the frequency and the voltage, and stores the value.

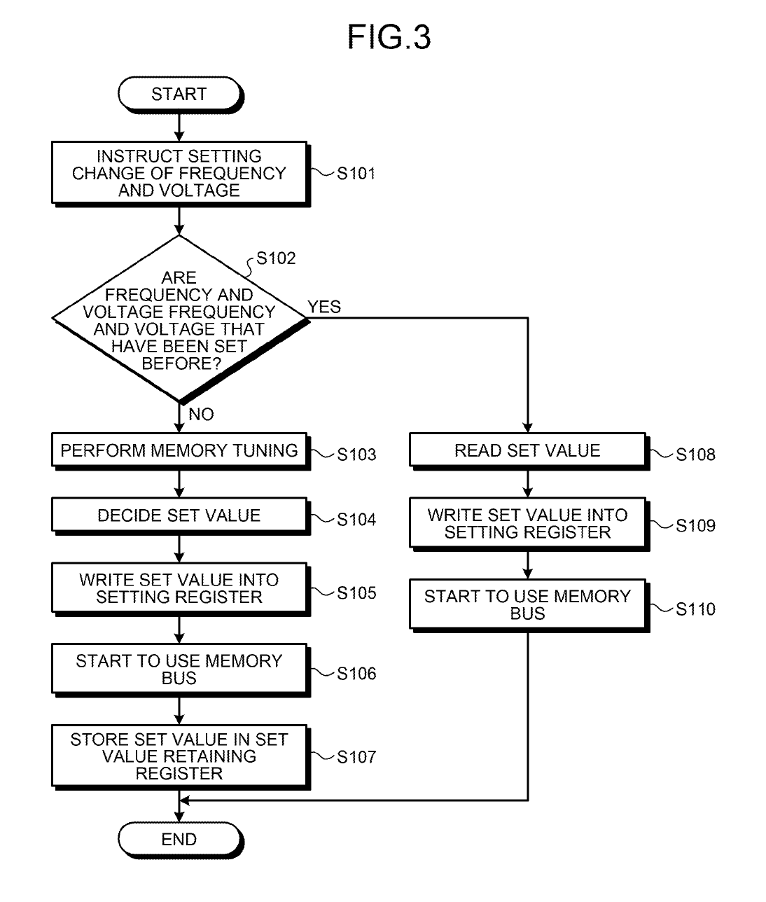

In the following, the flow of a memory control process performed by a memory control device according to the first embodiment will be described with reference to FIG. 3. FIG. 3 is a flowchart illustrating the flow of a memory control process performed by a memory control device according to the first embodiment.

The CPU 6 instructs the clock/voltage setting circuit 3 to change the setting of the frequency and the voltage (Step S101). The clock/voltage setting circuit 3 notifies the memory access control circuit 11 of the setting of the frequency and the voltage specified by the CPU 6.

The memory access control circuit 11 checks whether the control information that is associated with the setting of the notified frequency and the voltage is stored in the set value retaining register 14 and determines whether the notified frequency and the voltage are the frequency and the voltage that have been set before (Step S102).

If the notified frequency and the voltage are not the frequency and the voltage that have been set before (No at Step S102), the memory access control circuit 11 instructs the memory tuning circuit 13 to perform the memory tuning. In response to the instruction from the memory access control circuit 11, the memory tuning circuit 13 performs the memory tuning by using the clock and the voltage that are supplied at that time (Step S103).

Then, the memory tuning circuit 13 decides a set value in the control information associated with the voltage and the clock frequency that are supplied at that time (Step S104). Then, the memory tuning circuit 13 notifies the data transmission/reception module 12 of the decided set value.

The data transmission/reception module 12 resets the setting register 15 and then newly writes the notified set value into the setting register 15 (Step S105).

Then, the data transmission/reception module 12 controls the memory module 2 by using the set value retained in the setting register 15 and then starts to use a memory bus (Step S106).

The memory tuning circuit 13 stores, in the set value retaining register 14, the set value that has been decided and that is associated with the frequency and the voltage (Step S107).

In contrast, if the notified frequency and the voltage are the frequency and the voltage that are set before (Yes at Step S102), the memory access control circuit 11 notifies the data transmission/reception module 12 of the setting of the specified frequency and the voltage.

The data transmission/reception module 12 reads, from the set value retaining register 14, the set value in the control information that is associated with the notified frequency and the voltage (Step S108).

Then, the data transmission/reception module 12 resets the setting register 15 and newly writes the read set value into the setting register 15 (Step S109).

Thereafter, the data transmission/reception module 12 controls the memory module 2 by using the set value retained in the setting register 15 and starts to use a memory bus (Step S110).

As described above the memory control device according to the first embodiment stores therein a set value included in control information that is associated with the frequency and the voltage that are decided by the tuning and then controls a memory by using a set value that is stored when the same setting of the frequency and the voltage is specified again. Consequently, the number of times of the memory tuning to be performed can be reduced and thus the load applied to the system due to the memory tuning can be reduced.

Furthermore, because it is possible to reduce the time taken for the tuning when the setting of the frequency and the voltage is changed, the time taken to change the setting of the frequency and the voltage can be shortened.

Furthermore, for example, if the tuning is performed every time the setting of the frequency and the voltage is changed, the time taken for the tuning is increased in proportion to the number of changes; however, in the first embodiment, the time taken for the tuning is not increased even if the number of changes is increased. Consequently, the processing time of the information processing apparatus can be reduced.

In the following, the advantage provided when the memory controller 1 according to the first embodiment will specifically be described. For example, if a power supply that can be changed within 1 mV/1 μs, it takes 150 μs to change the setting of the voltage. Furthermore, for example, it takes 6 μs to change a clock due to the DRAM standard. Furthermore, the time taken for the memory tuning performed on 4 RANK-DIMM is, for example, 230 μs.

In other words, when the memory tuning is performed, the processing time taken to change the setting of the frequency and the voltage is 150 μs+6 μs+230 μs=386 μs.

In contrast, if it is assumed that the operation of the set value retaining register 14 is performed at the same speed as that of the clock of the memory module 2, when the set value retaining register 14 is used, the processing time taken to change the setting of the frequency and the voltage is 150 μs+6 μs+few ns≈156 μs. Here, the term of “few ns” indicates the time taken to read, for example, a set value from the set value retaining register 14.

As described above, by using the set value retaining register 14, the processing time can be reduced by 60% compared with a case in which the tuning is performed. Because the setting of the frequency and the voltage is often changed when the information processing apparatus is running, the time taken for the initial tuning can be ignored from the viewpoint of the whole operation, the processing time taken for the information processing apparatus seems to be practically reduced by 60%.

Furthermore, in the first embodiment, the number of types of the setting of the frequency and the voltage is three. However, if the number of types is four or more is used for the setting, the number of times tuning is performed may be once for each setting as long as a set value retaining register is arranged for all of the settings that are used and thus the same advantage is provided.

### [b] Second Embodiment

In the following, a second embodiment will be described. A memory control device according to the second embodiment differs from the memory control device in the first embodiment in that the tuning for each type of the setting of the frequency and the voltage is performed when the system is booted up. An information processing apparatus according to the second embodiment is also illustrated by the diagram in FIG. 1. In the description below, descriptions of the units having the same functions as those performed by the units in the first embodiment will be omitted.

When the tuning of the normal setting is ended after the information processing apparatus has been booted up, the CPU 6 selects the setting of another frequency and voltage. Then, the CPU 6 notifies the clock/voltage setting circuit 3 of a setting change in the selected frequency and the voltage. The CPU 6 repeatedly notifies the clock/voltage setting circuit 3 of a setting change until the tuning has been performed on all of the settings of the previously determined frequency and the voltage.

The clock/voltage setting circuit 3 notifies the memory access control circuit 11 of the normal setting as the setting of the frequency and the voltage when the information processing apparatus is booted up. Then, in accordance with the notification of the setting change received from the CPU 6, the clock/voltage setting circuit 3 sequentially notifies the memory access control circuit 11 of the setting of the frequency and the voltage.

When the information processing apparatus is booted up, the memory access control circuit 11 receives the frequency and the voltage that are used for the normal setting. Then, the memory access control circuit 11 sequentially receives the setting of another frequency and the voltage from the clock/voltage setting circuit 3. Thereafter, the memory access control circuit 11 sequentially instructs the memory tuning circuit 13 to perform the memory tuning on all of the setting of the frequency and the voltage, starting from the normal setting.

When the information processing apparatus is booted up, the memory tuning circuit 13 receives, from the memory access control circuit 11, an instruction to perform the memory tuning on all of the settings of the frequency and the voltage, starting from the normal setting. Then, the memory tuning circuit 13 sequentially performs the memory tuning on the setting of each of the frequencies and the voltages in accordance with the instruction. Then, the memory tuning circuit 13 associates the set value included in the control information that is decided by the tuning with the setting of the frequency and the voltage and then stored the value in the set value retaining register 14.

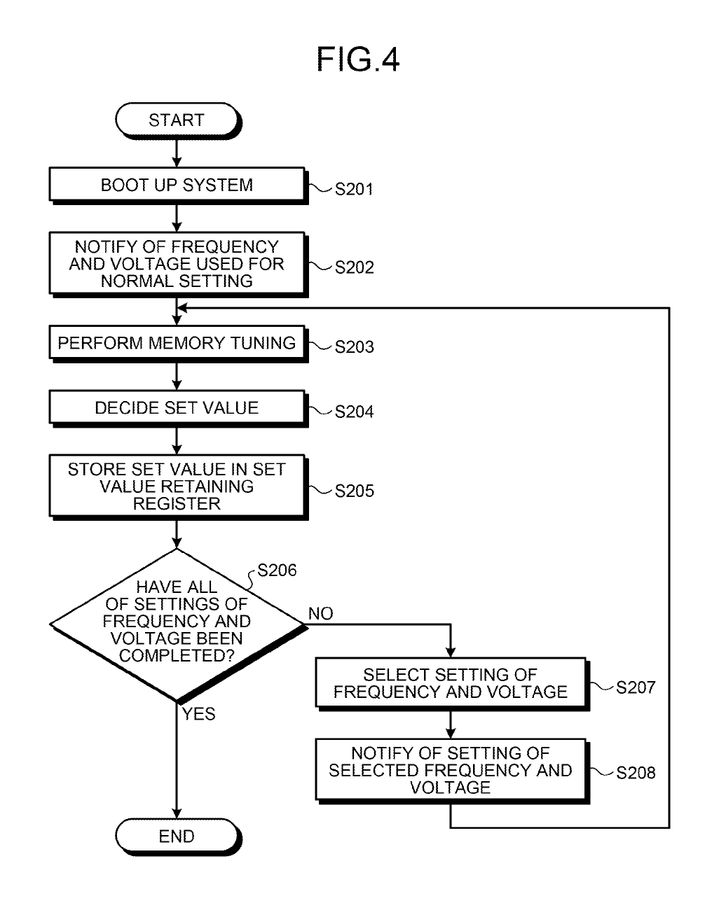

In the following, a memory control process performed, at the time of booted up, by the memory control device according to the second embodiment will be described with reference to FIG. 4. FIG. 4 is a flowchart illustrating the flow of the memory control process performed by a memory control device according to a second embodiment when a system is booted up.

When an operator turns on the power supply of the information processing apparatus, the system is booted up (Step S201).

The clock/voltage setting circuit 3 notifies the memory access control circuit 11 of the frequency and the voltage used for the normal setting. Then, the memory access control circuit 11 notifies the memory tuning circuit 13 of the frequency and the voltage that are used for the normal setting (Step S202).

The memory tuning circuit 13 performs the memory tuning by using the frequency and the voltage notified by the memory access control circuit 11 (Step S203).

Then, The memory tuning circuit 13 decides the set value included in the control information that is associated with the frequency and the voltage notified by the memory access control circuit 11 (Step S204).

Then, the memory tuning circuit 13 associates the decided set value with the setting of the frequency and the voltage notified by the memory access control circuit 11 and stores the values in the set value retaining register 14 (Step S205).

The CPU 6 determines whether decision of the set value included in the control information has been completed for all of the frequencies and the voltages (Step S206). In the second embodiment, for the three types of the settings, i.e., the normal setting, the high performance setting, and the low electrical power consumption setting, a set value included in control information, the CPU 6 determines whether the decision has been completed.

For the setting of the frequency and the voltage, if the decision of the set value included in the control information has not been completed (No at Step S206), the CPU 6 newly selects the setting of the frequency and the voltage (Step S207).

Then, the CPU 6 notifies the clock/voltage setting circuit 3 of the setting of the newly selected frequency and the voltage. The clock/voltage setting circuit 3 notifies the memory access control circuit 11 of the setting of the newly selected frequency and the voltage. Then, the memory access control circuit 11 notifies the memory tuning circuit 13 of the setting of the newly selected frequency and the voltage (Step S208).

In contrast, if the decision of the set value included in the control information has been completed for all of the frequencies and the voltages (Yes at Step S206), the memory controller 1 and the CPU 6 end the process for the decision of the set value included in the control information.

As described above, the memory control device according to the second embodiment performs, when the information processing apparatus is booted up, the memory tuning on all of the settings of the frequency and the voltage; decides the set values included in the associated control information; and stores the values. Consequently, when the information processing apparatus is operated after the start process is performed, it is possible to control the memory by using the set value included in the already stored control information and thus it is possible to avoid the memory tuning that is performed when the information processing apparatus is being operated. Specifically, it is possible to reduce the processing load applied when the information processing apparatus is being operated. Furthermore, it is possible to reduce an increase in the processing time due to a change in the frequency and the voltage during the operation.

### [c] Third Embodiment

In the following, a third embodiment will be described. It is conceivable that the setting of the control information on a memory is affected by a temperature change. Consequently, the set value that is decided by the tuning performed when the temperature has been changed may sometimes be different from the set value obtained before the temperature is changed. Thus, different control information may sometimes preferably be used depending on a temperature change. Accordingly, the memory control device according to the third embodiment differs from the first embodiment in that the set value included in the control information is decided for each temperature in addition to the setting of the frequency and the voltage.

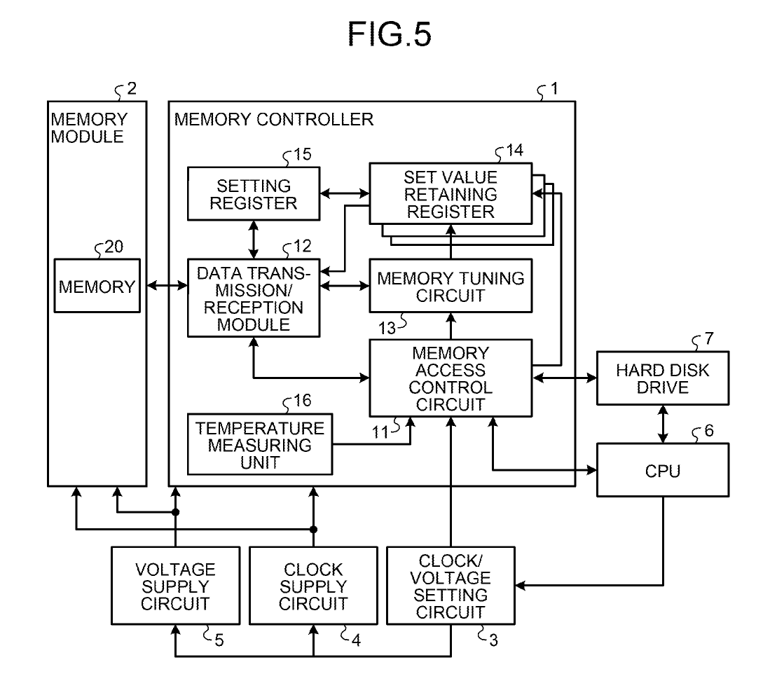

FIG. 5 is a block diagram illustrating an information processing apparatus according to a third embodiment. In addition to the configuration in the first embodiment, the memory controller 1 according to the third embodiment further includes a temperature measuring unit 16. In the description below, descriptions of the units having the same functions as those performed by the units in the first embodiment will be omitted.

The temperature measuring unit 16 measures the temperature in the vicinity of the memory module 2. Then, the temperature measuring unit 16 outputs information on the measured temperature to the memory access control circuit 11.

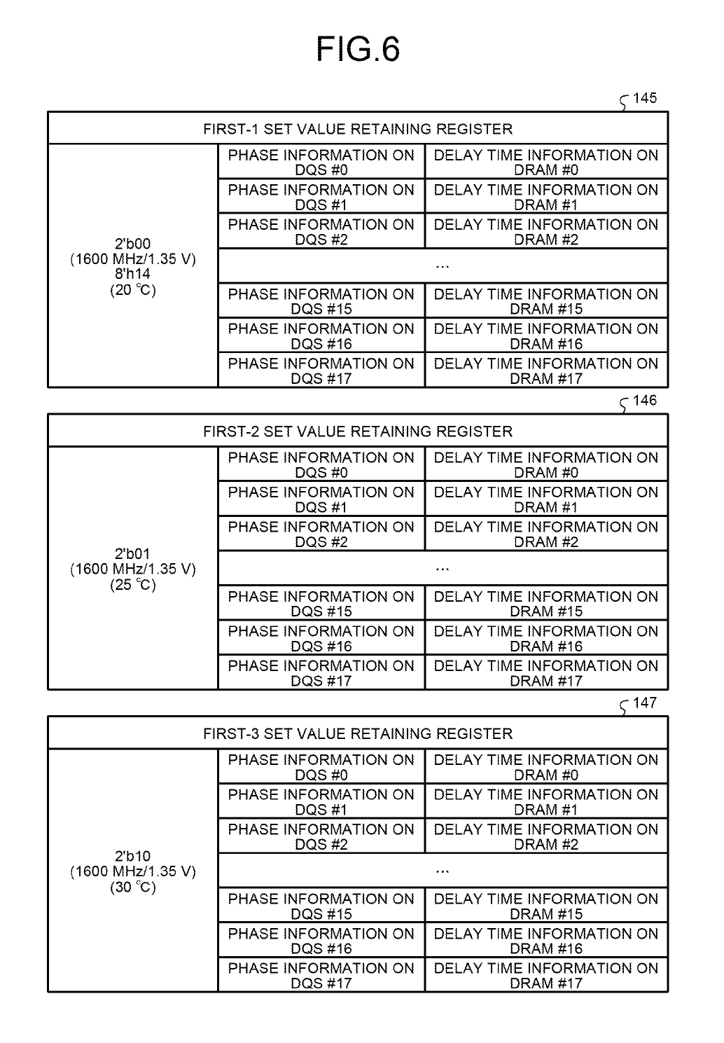

FIG. 6 is a schematic diagram illustrating information stored in a set value retaining register according to the third embodiment. As illustrated in FIG. 6, the set value retaining register 14 stores therein setting information for each setting of the frequency and the voltage at a different temperature.

A first-1 set value retaining register 145 stores therein a set value included in control information that is obtained when the frequency and the voltage for the normal setting are used and the temperature is 20° C. A first-2 set value retaining register 146 stores therein a set value included in control information that is obtained when the frequency and the voltage for the normal setting are used and the temperature is 25° C. A first-3 set value retaining register 147 stores therein a set value included in control information that is obtained when the frequency and the voltage for the normal setting are used and the temperature is 30° C.

Here, for convenience of explanation, FIG. 6 illustrates the first-1 set value retaining register 145 to the first-3 set value retaining register 147 each of which stores therein setting information for each temperature used in the normal setting; however, for another settings, setting information is also stored for each temperature. Furthermore, FIG. 6 illustrates the temperature at three stages, i.e., 20° C., 25° C., and 30° C.; however, the minimum temperature may also be lower and the maximum temperature may also be higher. Furthermore, in the third embodiment, because it is assumed that the state of a memory is changed if the absolute value of a temperature change exceeds 5° C., a temperature range is set to 5° C.; however, the temperature range may also be set to smaller or set to wider.

The memory access control circuit 11 receives a notification of the setting of the frequency and the voltage from the clock/voltage setting circuit 3. Furthermore, the memory access control circuit 11 receives an input of the measurement temperature from the temperature measuring unit 16.

The memory access control circuit 11 determines whether the notified frequency and the voltage are the frequency and the voltage that have been set before.

If the notified frequency and the voltage are the frequency and the voltage that have been set before, the memory access control circuit 11 determines whether the control information associated with the measurement temperature is stored in the set value retaining register 14. At this point, if the measurement temperature is in the allowable range of ±5° C. the temperature that has already been stored in the set value retaining register 14, the memory access control circuit 11 determines that the control information that is associated with that combination is stored in the set value retaining register 14.

If the target control information is stored in the set value retaining register 14, the memory access control circuit 11 notifies the data transmission/reception module 12 of the notified frequency, the notified voltage, and the measurement temperature.

In contrast, if the notified frequency and the voltage have not been set before or if the measurement temperature is out of the allowable range of the temperature stored in the set value retaining register 14, the memory access control circuit 11 instructs the memory tuning circuit 13 to perform the memory tuning.

The memory tuning circuit 13 receives the instruction to perform the memory tuning from the memory access control circuit 11.

Then, the memory tuning circuit 13 performs the memory tuning by using the voltage and the clock frequency used at that time. Then, the memory tuning circuit 13 decides a set value in the control information that is associated with the voltage and the clock frequency at that time.

Thereafter, the memory tuning circuit 13 notifies the data transmission/reception module 12 of the decided set value. Furthermore, the memory tuning circuit 13 receives the values of the frequency and the voltage at that time and also receives the temperature information from the memory access control circuit 11; sets the frequency and the voltage; associates the frequency and the voltage with the temperature; and then stores the set value of the decided control information in the set value retaining register 14.

At this point, in the third embodiment, because the capacity of the set value retaining register 14 is sufficient, the memory tuning circuit 13 stores all pieces of the decided setting information in the set value retaining register 14.

However, there may be a case in which the capacity of the set value retaining register 14 is small. In such a case, for example, the maximum number of pieces of control information that can be stored in the set value retaining register 14 is determined in advance. If the number of pieces of information that have already been stored reaches the upper limit, the memory tuning circuit 13 deletes the oldest stored control information and then newly stores the control information. Furthermore, the upper limit may preferably be set in accordance with the operation, such as the upper limit of the total number of pieces of information, the upper limit of the setting of the frequency and the voltage, or the upper limit for each temperature.

The data transmission/reception module 12 receives the setting of the frequency and the voltage and the measurement temperature from the memory access control circuit 11. Then, the data transmission/reception module 12 acquires the setting of the frequency and the voltage and also acquires a set value included in the control information that is associated with the measurement temperature. However, the data transmission/reception module 12 acquires the set value in the control information that is associated with the temperature in the range of ±5° C. with respect to the measurement voltage as a set value in the control information that is associated with the measurement temperature.

Then, the data transmission/reception module 12 controls the memory module 2 by using the acquired set value.

Furthermore, when the data transmission/reception module 12 receives a set value included in the control information from the memory tuning circuit 13, the data transmission/reception module 12 controls the memory module 2 by using the received set value.

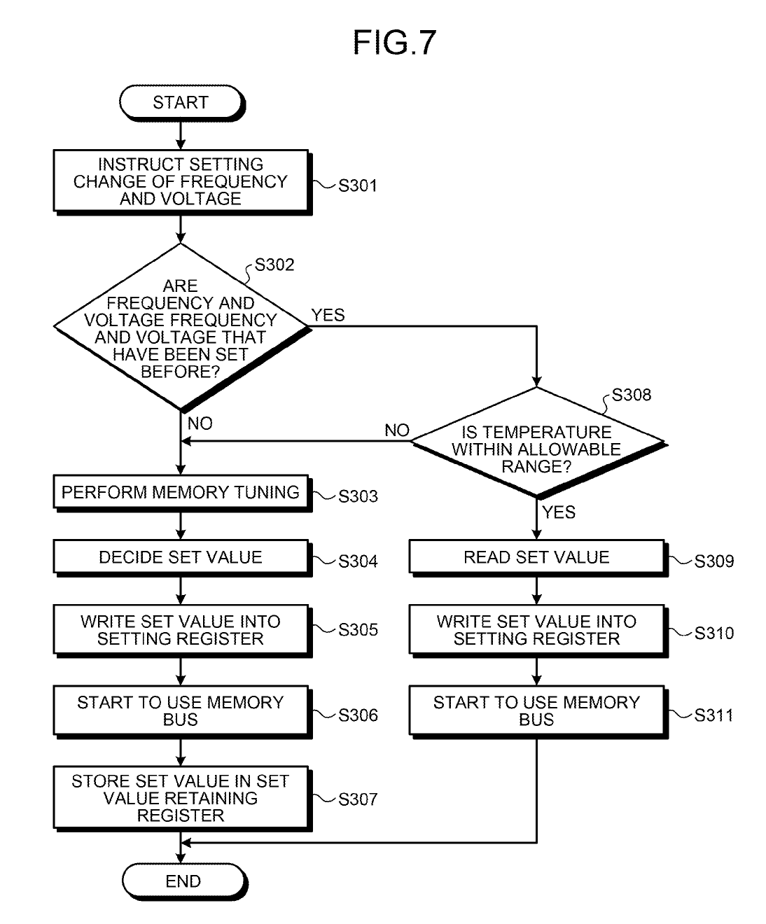

In the following, a memory control process performed by a memory control device according to the third embodiment will be described with reference to FIG. 7. FIG. 7 is a flowchart illustrating the flow of a memory control process performed by the memory control device according to the third embodiment.

The CPU 6 instructs the clock/voltage setting circuit 3 to change the setting of the frequency and the voltage (Step S301). The clock/voltage setting circuit 3 notifies the memory access control circuit 11 of the setting of the frequency and the voltage specified by the CPU 6.

The memory access control circuit 11 checks whether the control information that is associated with the notified frequency and the voltage is present in the set value retaining register 14 and then determines whether the frequency and the voltage are the frequency and the voltage that have been set before (Step S302).

If the frequency and the voltage are not the frequency and the voltage that have been set before (No at Step S302), the memory access control circuit 11 instructs the memory tuning circuit 13 to perform the memory tuning. In response to the instruction from the memory access control circuit 11, the memory tuning circuit 13 performs the memory tuning by using the clock and the voltage supplied at that time (Step S303).

Then, the memory tuning circuit 13 decides a set value included in the control information that is associated with the voltage and the clock frequency supplied at that time (Step S304). Then, the memory tuning circuit 13 notifies the data transmission/reception module 12 of the decided set value.

The data transmission/reception module 12 resets the setting register 15 and newly writes the notified set value to the setting register 15 (Step S305).

Thereafter, the data transmission/reception module 12 controls the memory module 2 by using the set value retained by the setting register 15 and starts to use a memory bus (Step S306).

The memory tuning circuit 13 associates the frequency and the voltage with the measurement temperature and then stores the decided set value in the set value retaining register 14 (Step S307).

In contrast, if the frequency and the voltage are the frequency and the voltage that have been set before (Yes at Step S302), the memory access control circuit 11 determines whether the measurement temperature is within the allowable range of the temperature at which the frequency and the voltage have been set before (Step S308). If the measurement temperature is not within the allowable range of the temperature (No at Step S308), the memory access control circuit 11 proceeds to Step S303.

In contrast, if the measurement temperature is within the allowable range of the temperature (Yes at Step S308), the memory access control circuit 11 notifies the data transmission/reception module 12 of the measurement temperature and the setting of the specified frequency and the voltage. The data transmission/reception module 12 reads, from the set value retaining register 14, the setting of the frequency and the voltage and also reads the set value included in the control information that is associated with the notified temperature, which is within the allowable range, of the measurement temperature (Step S309).

Then, the data transmission/reception module 12 resets the setting register 15 and newly writes the read set value to the setting register 15 (Step S310).

Thereafter, the data transmission/reception module 12 controls the memory module 2 by using the set value retained by the setting register 15 and starts to use a memory bus (Step S311).

As described above, the memory control device according to the third embodiment decides a set value included in control information by associating the set value with the combination of a temperature and the setting of the frequency and the voltage and then stores therein the decided set value included in control information. Consequently, the memory control device can cope with a needed setting change in a memory due to a temperature change and can promptly provide more appropriate tuning. Furthermore, when tuning is performed by taking into consideration a temperature, the processing load or the processing time can also be reduced.

(Modification)

In each of the embodiments described above, memory tuning is performed after an information processing apparatus is booted up and then the decided set value in the control information is retained. However, if a set value in control information that is associated with the setting of a frequency and a voltage does not vary and is almost constant, the control information that has been decided before may also be used when the information processing apparatus is booted up next time without performing tuning every time the boot up is performed.

For example, it is assumed that the set value retaining register 14 is a nonvolatile memory. The memory tuning circuit 13 performs the memory tuning and stores the decided set value in the control information in the set value retaining register 14 that is the nonvolatile memory. If the control information that is associated with the specified setting of the frequency and the voltage is stored in the set value retaining register 14 that is the nonvolatile memory, the memory access control circuit 11 notifies the data transmission/reception module 12 of the setting of the specified frequency and the voltage. Then, the data transmission/reception module 12 reads, from the set value retaining register 14 that is the nonvolatile memory, the set value included in the control information that is associated with the specified frequency and the voltage and then controls the memory module 2.

Because the nonvolatile memory does not loose retained data even when a power supply is turned off, in this case, the set value retaining register 14 continues retaining the set value in the control information that is associated with the setting of each of the decided frequency and the voltage after the information processing apparatus is booted up. Consequently, even when the information processing apparatus is rebooted, the memory tuning circuit 13 does not need to perform the memory tuning and, furthermore, the data transmission/reception module 12 can control the memory module 2 by using the set value in the control information stored in the set value retaining register 14. Furthermore, in these embodiments, a description has been given of the control information that is associated with the setting of a frequency and a voltage; however, the memory module 2 may also be controlled by using a combination of a temperature and control information.

Furthermore, in the embodiments described above, a user who actually uses an information processing apparatus performs the memory tuning when the user uses the information processing apparatus and decides control information. However, if set values included in control information related to a memory are almost the same in the information processing apparatus, a manufacturer of the information processing apparatus may also perform the memory tuning by using the memory controller 1 according to each of the embodiments before the manufacturer ships the information processing apparatus and may also store, in advance in the set value retaining register 14, a set value to be included in control information. Consequently, the memory tuning is not performed when a user uses the information processing apparatus and thus the processing load and the processing time can be further reduced.

According to an aspect of an embodiment of the memory control device, the control method of the memory control device, and the information processing apparatus disclosed in the present invention, an advantage is provided in that it is possible to reduce the time taken to change setting of a frequency and a voltage.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A memory control device comprising:
a storing unit that stores therein, in an associated manner, control information on a memory and a clock frequency that is supplied to the memory;
a determining unit that receives a specification of a clock frequency supplied to the memory and that determines whether control information that is associated with the specified clock frequency is present in the storing unit;
a deciding unit that decides, when the determining unit determines that the control information associated with the specified clock frequency is not present in the storing unit, the control information that is associated with the specified clock frequency; and
a control unit that controls, on the basis of the control information decided by the deciding unit, the memory when the determining unit determines that the control information associated with the specified clock frequency is not present in the storing unit.

2. The memory control device according to claim 1, wherein, when the determining unit determines that the control information associated with the specified clock frequency is present in the storing unit, the control unit controls the memory on the basis of the control information acquired from the storing unit.

3. The memory control device according to claim 1, wherein
the determining unit receives, when the memory control device is booted up, a combination of a predetermined type of clock frequency and a voltage supplied to the memory, and
the deciding unit decides control information associated with the combination of the predetermined type of clock frequency and the voltage and allows the storing unit to store therein the control information.

4. The memory control device according to claim 1 further comprising a temperature measuring unit that measures a temperature of the memory, wherein
the storing unit stores therein, in an associated manner, the control information, the clock frequency, the voltage, and the temperature,
the determining unit determines whether the control information that is associated with the specified clock frequency and the temperature measured by the temperature measuring unit is present in the storing unit, and
when the control information is present in the storing unit, the control unit acquires the control information from the storing unit and, when the control information is not present in the storing unit, the control unit acquires, from the deciding unit, control information that is decided as the control information associated with the specified clock frequency and controls the memory on the basis of the acquired control information.

5. The memory control device according to claim 1, wherein the control unit controls sending and receiving data to and from the memory.

6. The memory control device according to claim 1, wherein the control information is phase adjustment information that is used to adjust the phase of an input signal received from the memory and a reference signal, cycle adjustment information that is used to adjust the cycle, and delay information on the memory.

7. The memory control device according to claim 1, wherein, for the clock frequency and the voltage, at least a first setting, a second setting in which a processing speed of the memory is higher than the processing speed of the memory in the first setting, and a third setting in which electrical power consumption is lower than the electrical power in the first setting are present.

8. A control method of a memory control device that includes a storing unit that stores therein, in an associated manner, control information on a memory and a clock frequency that is supplied to the memory, the control method of the memory control device comprising:
receiving, performed by a determining unit included in the memory control device, a specification of a clock frequency supplied to the memory and determining, performed by the determining unit, whether control information associated with the specified clock frequency is present in the storing unit;
deciding, performed by a deciding unit included in the memory control device when the determining unit determines that the control information associated with the specified clock frequency is not present in the storing unit, the control information that is associated with the specified clock frequency; and
controlling, performed by a control unit included in the memory control device on the basis of the control information decided by the deciding unit, the memory when the determining unit determines that the control information associated with the specified clock frequency is not present in the storing unit.

9. An information processing apparatus comprising:
a central processing unit (CPU);
a memory;
a clock supply circuit; and
a memory control device, wherein
the clock supply circuit supplies a clock to the memory, and
the memory control device includes
a storing unit that stores therein, in an associated manner, control information on the memory and a clock frequency that is supplied to the memory,
a determining unit that receives a specification of a clock frequency supplied to the memory and that determines whether control information that is associated with the specified clock frequency is present in the storing unit,
a deciding unit that decides, when the determining unit determines that the control information associated with the specified clock frequency is not present in the storing unit, the control information that is associated with the specified clock frequency, and
a control unit that controls, on the basis of the control information decided by the deciding unit, the memory when the determining unit determines that the control information associated with the specified clock frequency is not present in the storing unit.
